(19) United States
(12) Patent Application Publication
(10) Pub. No.: US 2026/0235901 A1
(43) Pub. Date: Aug. 13, 2026

(54) WIRING SUBSTRATE AND DISPLAY DEVICE

(71) Applicant: SHARP KABUSHIKI KAISHA, Sakai City (JP)

(72) Inventor: MASATOMO HONJO, Sakai City (JP)

(21) Appl. No.: 19/533,717

(22) Filed: Feb. 9, 2026

(30) Foreign Application Priority Data
Feb. 10, 2025 (JP) 2025-020078

(51) Int. Cl. G02F 1/1333; G02F 1/1335; H10D 86/40; H10D 86/60

(52) U.S. Cl. CPC G02F 1/133382; G02F 1/13338; G02F 1/133612; H10D 86/441; H10D 86/60

(57) ABSTRACT

A wiring substrate includes a first insulating film having a first insulating portion and a second insulating portion that is smaller in film thickness than is the first insulating portion, a first wire placed over the first insulating portion and composed of part of a first conducting film placed at a higher layer than the first insulating film, a second wire placed over the second insulating portion and composed of part of the first conducting film, and a second insulating film, placed at a high layer than the first conducting film, that has a third insulating portion disposed not to overlap the first wire and to overlap the second wire.

### BACKGROUND

### 1. Field

The present disclosure relates to a wiring substrate and a display device with a reduction in the number of manufacturing steps and a reduction in warpage.

### 2. Description of the Related Art

In the related art, as an example of a display device including a wiring substrate, a liquid crystal display device disclosed in Japanese Unexamined Patent Application Publication No. 2022-105299 has been known. Japanese Unexamined Patent Application Publication No. 2022-105299 discloses a touch display device that is a display device including an element substrate as a wiring substrate. The touch display device disclosed in Japanese Unexamined Patent Application Publication No. 2022-105299 includes a link wire located over the element substrate, an upper planarizing film, located over the element substrate, that includes a link contact hole through which the link wire is partially exposed, a bank insulating film, located over the upper planarizing film, that includes a first opening defining a light-emitting region and a second opening overlapping part of the link wire, a light-emitting element, located in the light-emitting region, that includes a pixel electrode, a light-emitting layer, and an upper electrode stacked in this order over the upper planarizing film, a separating partition wall, located over the bank insulating film, that has a side wall overlapping a side wall of the second opening and having an inverted tapered shape, and a sealing member located over the bank insulating film, the light-emitting element, and the separating partition wall. The second opening is located between the first opening and the separating partition wall, and the upper electrode of the light-emitting element has an end portion located in the second opening and coupled to the link wire.

In view of adding a wire to add a new function to the touch display device disclosed in Japanese Unexamined Patent Application Publication No. 2022-105299, it is of necessity to add a metal film that constitutes the wire and to add an insulating film so that the wire thus added and the link wire do not become short-circuited with each other. However, adding the metal film and the insulating film leads to an increase in the number of manufacturing steps accordingly and an increase in the number of insulating films, thereby subjecting the element substrate to increased film stress and making the element substrate prone to warpage as a result.

It is desirable to reduce the number of manufacturing steps and reduce warpage.

### SUMMARY

According to an aspect of the disclosure, there is provided a wiring substrate including a first insulating film having a first insulating portion and a second insulating portion that is smaller in film thickness than is the first insulating portion, a first wire placed over the first insulating portion and composed of part of a first conducting film placed at a higher layer than the first insulating film, a second wire placed over the second insulating portion and composed of part of the first conducting film, and a second insulating film, placed at a high layer than the first conducting film, that has a third insulating portion disposed not to overlap the first wire and to overlap the second wire.

According to an aspect of the disclosure, there is provided a display device including the wiring substrate and a counter substrate facing the wiring substrate.

### BRIEF DESCRIPTION OF THE DRAWINGS

FIG. 1 is a plan view of a liquid crystal panel, a flexible substrate, a control substrate, or other components of a liquid crystal display device according to Embodiment 1;

FIG. 2 is a cross-sectional view of the liquid crystal panel, the flexible substrate, the control substrate, or other components according to Embodiment 1;

FIG. 3 is a circuit diagram showing an electrical configuration of an array substrate of the liquid crystal panel according to Embodiment 1;

FIG. 4 is a plan view showing a configuration pertaining to a touch panel function and a configuration pertaining to a heater function of the array substrate according to Embodiment 1;

FIG. 5 is a cross-sectional view showing a cross-sectional configuration of a pixel electrode or other components of the array substrate according to Embodiment 1 as taken along an X-axis direction;

FIG. 6 is a cross-sectional view showing a cross-sectional configuration of a TFT and a touch wire of the array substrate according to Embodiment 1 and an area therearound; and

FIG. 7 is a cross-sectional view showing a cross-sectional configuration of a TFT and a heater wire of the array substrate according to Embodiment 1 and an area therearound.

### DESCRIPTION OF THE EMBODIMENTS

### Embodiment 1

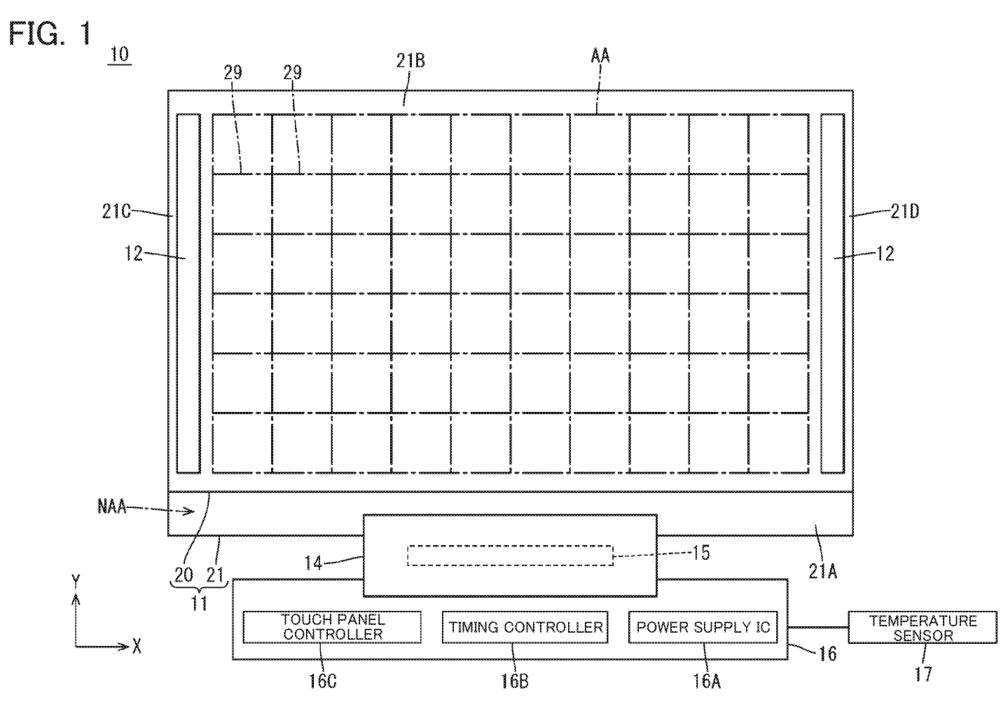

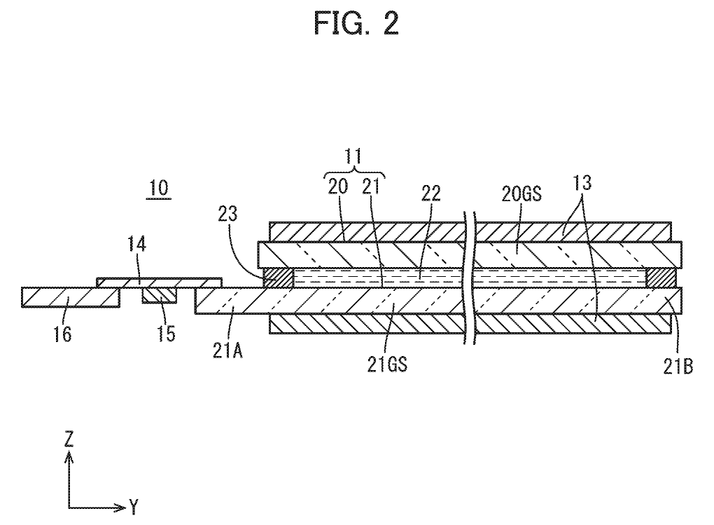

Embodiment 1 is described with reference to FIGS. 1 to 7. The present embodiment illustrates a liquid crystal display device 10 that is used in an on-board CMS (camera monitor system). The on-board CMS is a system that, as a replacement for a side mirror or a rearview mirror using a mirror-finished surface in an automobile, displays, on a display (liquid crystal display device 10), an image taken by a camera. The liquid crystal display device 10 according to the present embodiment has a display function and a touch panel function (position input function). Note that some of the drawings show an X axis, a Y axis, and a Z axis and are drawn so that the direction of each axis is an identical direction in each drawing. Further, FIGS. 2 and 5 to 7 show front side up and back side down.

As shown in FIG. 1, the liquid crystal display device 10 includes at least a liquid crystal panel (display device, display panel) 11 that has a horizontally long rectangular shape and that is capable of displaying an image and a backlight device (lighting device) serving as an external light source that illuminates the liquid crystal panel 11 with light for use in display. The backlight device is placed at the back (behind) the liquid crystal panel 11 and includes a light source (e.g. an LED) that emits white light, an optical member that, by imparting an optical effect to light from the light source, converts the light into surface light, or other components. A central portion of a screen (principal surface) of the liquid crystal panel 11 serves as a display area AA where an image is displayed. On the other hand, a frame-shaped outer peripheral portion of the screen of the liquid crystal panel 11 that surrounds the display area AA serves as a non-display area NAA where the image is not displayed.

In the non-display area NAA of the liquid crystal panel 11, as shown in FIG. 1, a circuit unit (peripheral circuit unit, gate circuit unit) 12 is provided. A pair of the circuit units 12 are placed in such a manner that the display area AA is interposed therebetween in an X-axis direction. The circuit unit 12 is provided in a band-like area extending along a Y-axis direction. The circuit unit 12 is intended to supply a scanning signal to the after-mentioned gate wire 26 and is provided monolithically in the after-mentioned array substrate 21. The circuit unit 12 is a GDM (gate driver monolithic) circuit. The circuit unit 12 includes a shift register circuit that outputs a scanning signal at a predetermined timing, a buffer circuit for amplifying a scanning signal, or other circuits.

The liquid crystal panel 11 is described in detail with reference to FIG. 2 in addition to FIG. 1. As shown in FIGS. 1 and 2, the liquid crystal panel 11 includes a pair of substrates 20 and 21 bonded together. A front (frontward) one of the pair of substrates 20 and 21 is a counter substrate 20, and a back (backward) one of the pair of substrates 20 and 21 is an array substrate (wiring substrate) 21. The counter substrate 20 is obtained by forming a stack of various types of film on an inner surface of a glass substrate 20GS, and the array substrate 21 is obtained by forming a stack of various types of film on an inner surface of a glass substrate 21GS. Sandwiched between the pair of substrates 20 and 21 is a liquid crystal layer (medium layer) 22 containing liquid crystal molecules constituting a substance whose optical properties vary in the presence of the application of an electric field. Sandwiched between the outer edges of the pair of substrates 20 and 21 is a seal portion 23 that seals in the liquid crystal layer 22. The seal portion 23 is formed in a rectangular frame shape (endless annular shape) to surround the liquid crystal layer 22. Attached to outer surfaces of the two substrates 20 are polarizing plates 13, respectively.

As shown in FIGS. 1 and 2, the counter substrate 20 has short-side dimensions that are shorter than those of the array substrate 21. The counter substrate 20 is bonded to the array substrate 21 in such a manner that one end of the counter substrate 20 meets one end of the array substrate 21 in a short-side direction (Y-axis direction). Accordingly, the other end of the array substrate 21 in the short-side direction serves as a first end portion 21A exposed by projecting laterally from the counter substrate 20. The first end portion 21A is a side portion of the non-display area NAA, which has a frame shape, that extends along the X-axis direction, and is mounted with a flexible substrate 14 for supplying various types of signal. Further, one end of the array substrate 21 in the short-side direction serves as a second end portion 21B. The second end portion 21B is a side portion of the non-display area NAA, which has a frame shape, that extends along the X-axis direction, and the display area AA is interposed between the first end portion 21A and the second end portion 21B in the Y-axis direction. Further, one end (left end of FIG. 1) of the array substrate 21 in a long-side direction (X-axis direction) serves as a third end portion 21C, and the other end (right end of FIG. 1) of the array substrate 21 in the long-side direction serves as a fourth end portion 21D. The third end portion 21C and the fourth end portion 21D are both side portions of the non-display area NAA, which has a frame shape, that extend along the Y-axis direction. A pair of the circuit units 12 are placed in the third end portion 21C and the fourth end portion 21D.

The flexible substrate 14 is configured such that a large number of wiring patterns are formed on a base material composed of a synthetic resin material (such as polyimide resin) having insulating properties and flexibility. As shown in FIGS. 1 and 2, a driver 15 is mounted on the flexible substrate 14 by COF (Chip on Film). The driver 15 is composed of an LSI chip having a drive circuit inside. The driver 15 processes various types of signal that are transmitted by the flexible substrate 14. The driver 15 is intended to supply various types of signal (e.g. an image signal) to a wire (e.g. the after-mentioned source wire 27) of the display area AA. One end of the flexible substrate 14 is connected to the first end portion 21A of the array substrate 21, and the other end of the flexible substrate 14 is connected to a control substrate 16. The flexible substrate 14 is connected to a central portion of the first end portion 21A in the X-axis direction. The control substrate 16 is configured such that a plurality of circuit components are mounted on a rigid substrate made of synthetic resin (e.g. made of paper phenol or made of glass epoxy). The plurality of circuit components include a power supply IC (integrated circuit) 16A serving as a direct-current power supply for outputting electric power, a timing controller 16B that generates various types of signal to be supplied to the driver 15, a touch panel controller 16C that controls the touch panel function, a level shifter IC for controlling (stepping down and stepping up) a voltage level, or other components. The control substrate 16 has a connector area to which the flexible substrate 14 or other components are connected. The control substrate 16 is disposed to overlap the back of the backlight device by the flexible substrate 14 being bent in a turnover shape. Connected to the control substrate 16 is a temperature sensor 17. The temperature sensor 17 is placed in such a position as to be close to or in contact with the liquid crystal panel 11, and is enabled to detect the temperature of an area around the liquid crystal panel 11.

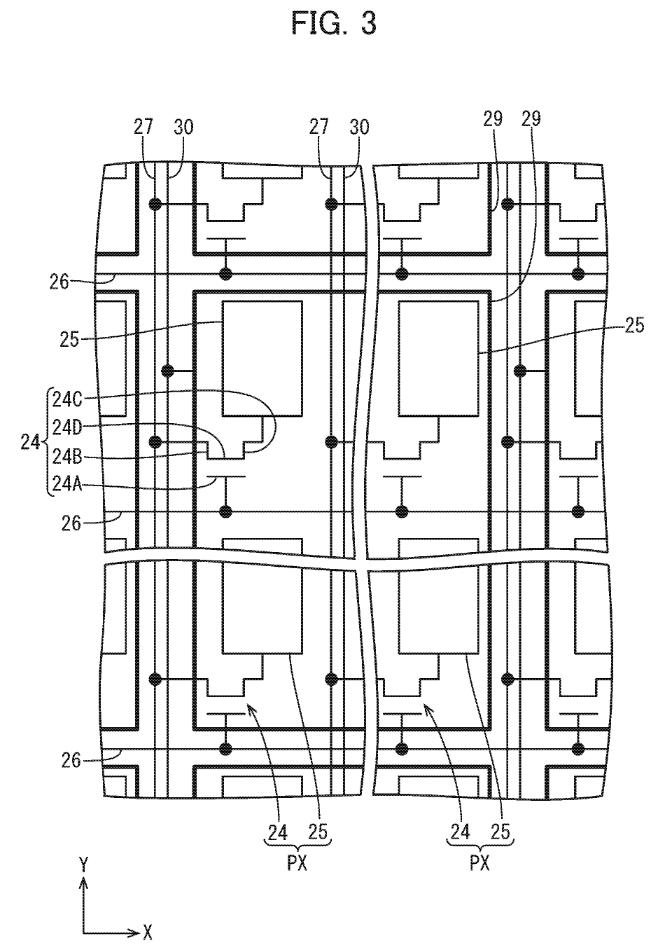

Next, a configuration of the array substrate 21 in the display area AA is described with reference to FIG. 3. As shown in FIG. 3, at least a TFT (switching element, transistor) 24 and a pixel electrode (fourth electrode) 25 are provided at the side of an inner surface of the array substrate 21 in the display area AA. The TFT 24 and the pixel electrode 25 constitute a pixel PX serving as a display unit together with the after-mentioned color filter. A plurality of the TFTs 24 and a plurality of the pixel electrodes 25 are provided in a matrix (rows and columns) by being arranged at spacings along the X-axis direction and the Y-axis direction. Arranged around this TFT 24 and this pixel electrode 25 are a gate wire (scanning wire) 26 and a source wire (image wire, signal wire) 27 that are orthogonal to (intersect) each other. The gate wire 26 extends along the X-axis direction, and includes a plurality of the gate wires 26 placed at spacings in the Y-axis direction. The source wire 27 extends along the Y-axis direction, and includes a plurality of the source wires 27 placed at spacings in the X-axis direction. The TFT 24 includes a gate electrode 24A connected to the gate wire 26, a source electrode 24B connected to the source wire 27, a drain electrode (second electrode) 24C connected to the pixel electrode 25, and a semiconductor component 24D connected to the source electrode 24B and the drain electrode 24C. Moreover, the TFT 24 is driven in accordance with a scanning signal supplied from the circuit unit 12 to the gate electrode 24A through the gate wire 26. Then, a potential pertaining to an image signal supplied from the driver 15 to the source electrode 24 through the source wire 27 is supplied to the drain electrode 24C via the semiconductor component 24D. As a result of that, the pixel electrode 25 is charged to the potential pertaining to the image signal. The pixel electrode 25 is placed in an area surrounded by the gate wire 26 and the source wire 27, and is, for example, substantially rectangular in planar shape.

Further, a plurality of color filters are provided in such a position on the counter substrate 20 in the display area AA as to be opposite to each pixel electrode 25 of the array substrate 21. The color filters are placed such that three colors of R (red), green (G), and B (blue) are repeatedly arranged in a predetermined order, and constitute pixels PX (red, green, and blue pixels) of each separate color together with the TFT 24 and the pixel electrode 25. The three pixels PX, namely the red, green, and blue pixels, constitute a display pixel that is capable of a color display of a predetermined tone. Further, a light shield (black matrix) for avoiding a mixture of colors is formed between one color filter and another. Provided on the innermost surfaces of the counter substrate 20 and the array substrate 21 are alignment films for aligning the liquid crystal molecules contained in the liquid crystal layer 22, respectively.

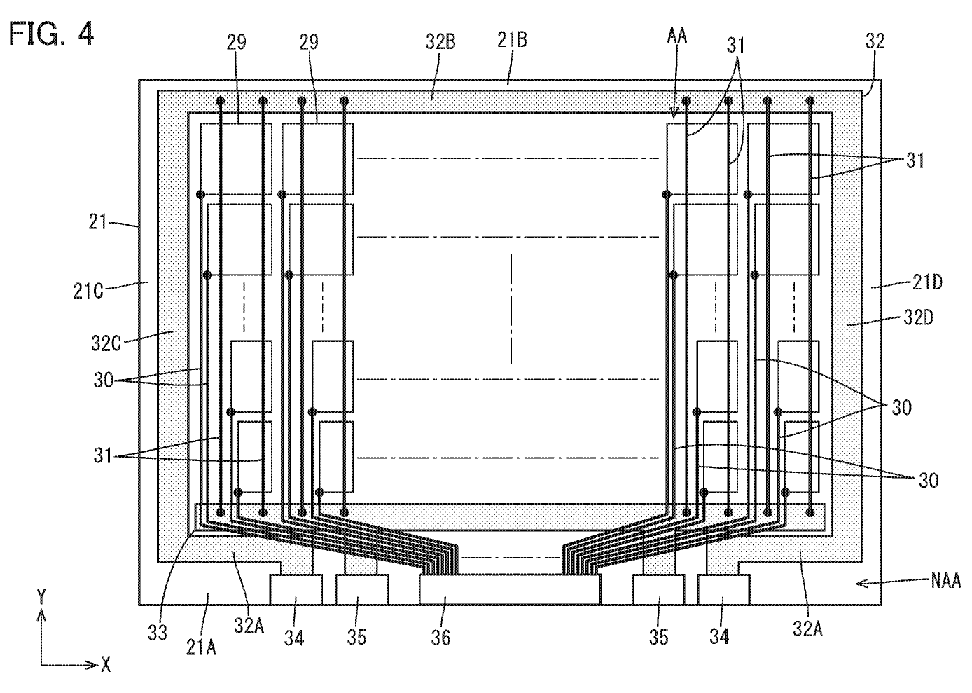

The liquid crystal panel 11 according to the present embodiment has a combination of the display function of displaying an image and the touch panel function of detecting a position (input position) that a user inputs on the basis of an image being displayed, and has integrated therewith (in an in-cell manner) a touch panel pattern for fulfilling the touch panel function. Furthermore, since the liquid crystal display device 10 according to the present disclosure is used in an on-board CMS, there tends to be strong concern that there may be a decrease in the response speed of the liquid crystal panel 11 due to an increase in the viscosity of the liquid crystal layer 22 in a cool environment. To address this problem, the liquid crystal panel 11 according to the present embodiment has a heater function for improving the response speed at low temperature, and has an in-cell configuration for fulfilling the heater function. A configuration pertaining to the touch panel function and a configuration pertaining to the heater function are described below with reference to FIG. 4 or other drawings.

A brief overview of the configuration pertaining to the touch panel function is given. The touch panel pattern for fulfilling the touch panel function is of a so-called projected capacitive type, and adopts a self-capacitive detecting scheme. As shown in FIG. 4, the touch panel pattern is constituted by a plurality of touch electrodes (first electrodes, position detecting electrodes) 29 placed side by side in a matrix in the principal surface of the liquid crystal panel 11. The touch electrodes 29 are placed in the display area AA of the liquid crystal panel 11. Accordingly, the display area AA of the liquid crystal panel 11 substantially coincides with a touch area (position input area) that is capable of detecting an input position, and the non-display area NAA substantially coincides with a non-touch area (non-position input area) that is incapable of detecting an input position. Moreover, when the user moves his/her finger (position input body) as an electric conductor toward a surface of the liquid crystal panel 11 in an attempt to do position input on the basis of an image that he/she views in the display area AA of the liquid crystal panel 11, capacitances are formed between the finger and touch electrodes 29. As a result, a capacitance that is detected by a touch electrode 29 located near the finger changes as the finger approaches, and becomes different from that which is detected by a touch electrode 29 located away from the finger, whereby it becomes possible to detect the input position. Note that the specific number of touch electrodes 29 that are provided are subject to appropriate change other than that illustrated in FIG. 4. Each of the touch electrodes 29 has a substantially square shape when seen in plan view, and has a dimension of approximately several millimeters on a side. Accordingly, each of the touch electrodes 29 is much larger in plan-view size than the pixel PX, and is disposed in an area covering a plurality of the pixels PX in the X-axis direction and the Y-axis direction.

At the side of the inner surface of the array substrate 21 in the display area AA, as shown in FIG. 4, a plurality of touch wires (first wires, position detecting wires) 30 connected to the plurality of touch electrodes 29 are provided. The touch wires 30 extend along the Y-axis direction and run parallel to the source wire 27. A plurality of the touch wires 30 are placed at spacings in the X-axis direction. A plurality of the touch wires 30 connected to a plurality of the touch electrodes 29 arranged along the Y-axis direction to form one line are unevenly distributed on one side (i.e. the left side of FIG. 4) in the X-axis direction of the plurality of touch electrodes 29 forming the line. Each of the plurality of touch electrodes 29 forming the line has a range of formation set in the X-axis direction so that the touch electrode 29 does not overlap a touch wire 30 to which the touch electrode 29 is not to be connected. The touch wires 30 are supplied with touch signals (position detection signals) pertaining to the touch panel function (see FIG. 1). Note that cross-sectional configurations or other configurations of the touch electrodes 29 and the touch wires 30 will be described in detail later.

Next, a brief overview of the configuration pertaining to the heater function is given. As shown in FIG. 4, the array substrate 21 is provided with a heater wire (second wire) 31, a first trunk wire 32, a second trunk wire 33, a first heater terminal area (first terminal area) 34, and a second heater terminal area (second terminal area) 35 as a components for fulfilling the heater function. Note that FIG. 4 illustrates each of the trunk wires 32 and 33 by half-tone dot meshing. The heater wire 31 is a wire that primarily fulfills a function of generating heat when energized, and includes a plurality of the heater wires 31 placed in the display area AA. Specifically, the plurality of heater wires 31 extend along the Y-axis direction from the first end portion 21A of the array substrate 21 to the second end portion 21B and longitudinally traverse the display area AA. Accordingly, the plurality of heater wires 31 longitudinally traverse all of a plurality of the touch electrodes 29 arranged along the Y-axis direction in the display area AA. The plurality of heater wires 31 are placed at spacings in the X-axis direction.

As shown in FIG. 4, the first trunk wire 31 and the second trunk wire 32 are both placed in the non-display area NAA. Specifically, the first trunk wire 32 is provided all over the first end portion 21A, the second end portion 21B, the third end portion 21C, and the fourth end portion 21D, which constitute the non-display area NAA. The first trunk wire 32 has, in both end portions of the first end portion 21A in the X-axis direction, two first wire constituting portions 32A extending along the X-axis direction. End portions of the first wire constituting portions 32A that face toward the center of the first end portion 21A in the X-axis direction extend along the Y-axis direction and are connected to the after-mentioned first heater terminal area 34. The first trunk wire 32 has, in the second end portion 21B, a second wire constituting portion 32B extending along the X-axis direction. The second wire constituting portion 32B is placed over substantially the entire length of the second end portion 21B in the X-axis direction, and overlaps and is connected to end portions of all heater wires 31 that face the second end portion 21B. The first trunk wire 32 has, in the third end portion 21C, a third wire constituting portion 32C extending along the Y-axis direction. The third wire constituting portion 32C is placed over substantially the entire length of the third end portion 21C in the Y-axis direction. One end portion of the third wire constituting portion 32C (that faces the first end portion 21A) is joined to a first wire constituting portion 32A, and the other end portion of the third wire constituting portion 32C (that faces the second end portion 21B) is joined to the second wire constituting portion 32B. The first trunk wire 32 has, in the fourth end portion 21D, a fourth wire constituting portion 32D extending along the Y-axis direction. The fourth wire constituting portion 32D is placed over substantially the entire length of the fourth end portion 21D in the Y-axis direction. One end portion of the fourth wire constituting portion 32D is joined to a first wire constituting portion 32A, and the other end portion of the fourth wire constituting portion 32D is joined to the second wire constituting portion 32B. The second trunk wire 33 is disposed in the first end portion 21A to extend along the X-axis direction. The second trunk wire 33 is placed over substantially the entire length of the first end portion 21A in the X-axis direction, and overlaps and is connected to end portions of all heater wires 31 that face the first end portion 21A. The second trunk wire 33 is located closer to the display area AA in the Y-axis direction than are the first wire constituting portions 32A of the first trunk wire 32. Part of the second trunk wire 33 extends along the Y-axis direction and is connected to the after-mentioned second heater terminal area 35.

As shown in FIG. 4, the first heater terminal area 34 and the second heater terminal area 35 are both provided in the first end portion 21A of the array substrate 21. Specifically, the first heater terminal area 34 and the second heater terminal area 35 are both placed in such a position in the first end portion 21A as to overlap the flexible substrate 14, and are connected via the anisotropic conductive film to a plurality of terminal areas of the flexible substrate 14. The heater terminal area 34 includes two heater terminal areas 34 placed at a distance from each other in the X-axis direction in the first end portion 21A. The two heater terminal areas 34 are connected to the two first wire constituting portions 32A of the first trunk wire 32, respectively. The two first heater terminal areas 34 are connected to positive electrode terminal areas included in the terminal areas of the flexible substrate 14 and connected to a positive electrode of the power supply IC (direct-current power supply) 16A, respectively. The second heater terminal area 35 includes two second heater terminal areas 35 placed at spacings in the X-axis direction in the first end portion 21A. The two second heater terminal areas 35 are placed closer to the center of the first end portion 21A in the X-axis direction than are the two first heater terminal areas 34 and adjacent to the two first heater terminal areas 34, respectively. The two second heater terminal areas 35 are each connected to the second trunk wire 33. The two second heating terminal areas 35 are connected to negative electrode terminal areas included in the terminal areas of the flexible substrate 14 and connected to a negative electrode of the power supply IC 16A, respectively.

In the present embodiment, as shown in FIG. 1, the heater function is controlled by the timing controller 16B of the control substrate 16. Specifically, the timing controller 16B can turn on and off the supply of electric power from the power supply IC 16A to the first heater terminal area 34 on the basis of the temperature of an area near the liquid crystal panel 11 as detected by the temperature sensor 17. Specifically, in a case where the temperature detected by the temperature sensor 17 is lower than a predetermined lower-limit reference value, the timing controller 16B turns on the supply of electric power from the power supply IC 16A to the first heater terminal area 34. Then, the heater wires 31 become energized, whereby heat is generated from the heater wires 31, so that the liquid crystal layer 22 or other components are heated by the heat. In a case where the temperature detected by the temperature sensor 17 exceeds a predetermined upper-limit reference value, the timing controller 16B turns off the supply of electric power from the power supply IC 16A to the first heater terminal area 34. Then, the heater wires 31 stop being energized, whereby no heat is generated from the heater wires 31 any longer, so that the temperature of the liquid crystal layer 22 or other components gradually drops. By thus keeping the temperature detected by the temperature sensor 17 between the lower-limit reference value and the upper-limit reference value, the temperature and viscosity of the liquid crystal layer 22 can be kept in a suitable condition. This makes it possible to improve the response speed of the liquid crystal panel 11 even in a cold environment and makes it possible to improve the display quality of an image.

Further, in the first end portion 21A of the array substrate 21, as shown in FIG. 4, a terminal group 36 composed of a plurality of terminal areas is provided in addition to the first heater terminal area 34 and the second heater terminal area 35. The terminal group 36 includes a plurality of display terminal areas and a plurality of touch panel terminal areas. FIG. 4 illustrates the terminal group 36 in a simplified manner in the shape of a block; however, in actuality, the plurality of display terminal areas and the plurality of touch panel terminal areas are placed at spacings in the X-axis direction. The plurality of display terminal areas included in the terminal group 36 are connected via source lead wires (not illustrated) to the plurality of source wires 27 placed in the display area AA. The plurality of touch panel terminal areas included in the terminal group 36 are connected via touch panel lead wires (not illustrated) to the plurality of touch wires 30 placed in the display area AA. As with the first heater terminal area 34 and the second heater terminal area 35, the plurality of display terminal areas and the plurality of touch panel terminal areas included in the terminal group 36 are placed in such a position in the first end portion 21A as to overlap the flexible substrate 14, and are connected via the anisotropic conductive film to the plurality of terminal areas of the flexible substrate 14. The terminals of the terminal group 36 are placed at spacings in the X-axis direction at least in a place interposed between the two second heater terminal areas 35 in the X-axis direction. Note that the plurality of display terminal areas and the plurality of touch panel terminal areas included in the terminal group 36 may include those placed at an end of each first heater terminal area 34 in the X-axis direction.

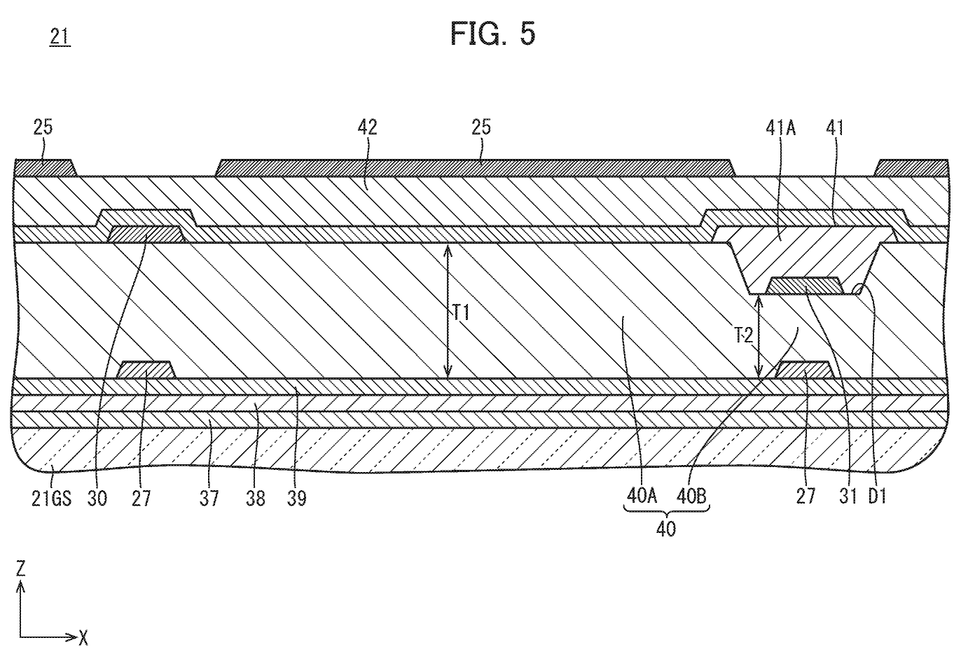

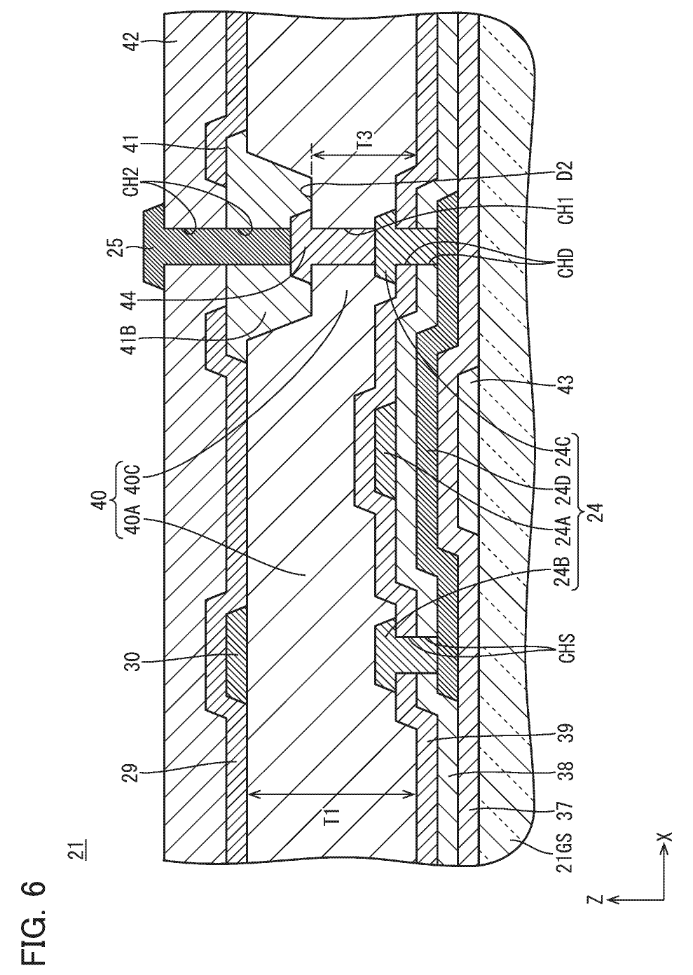

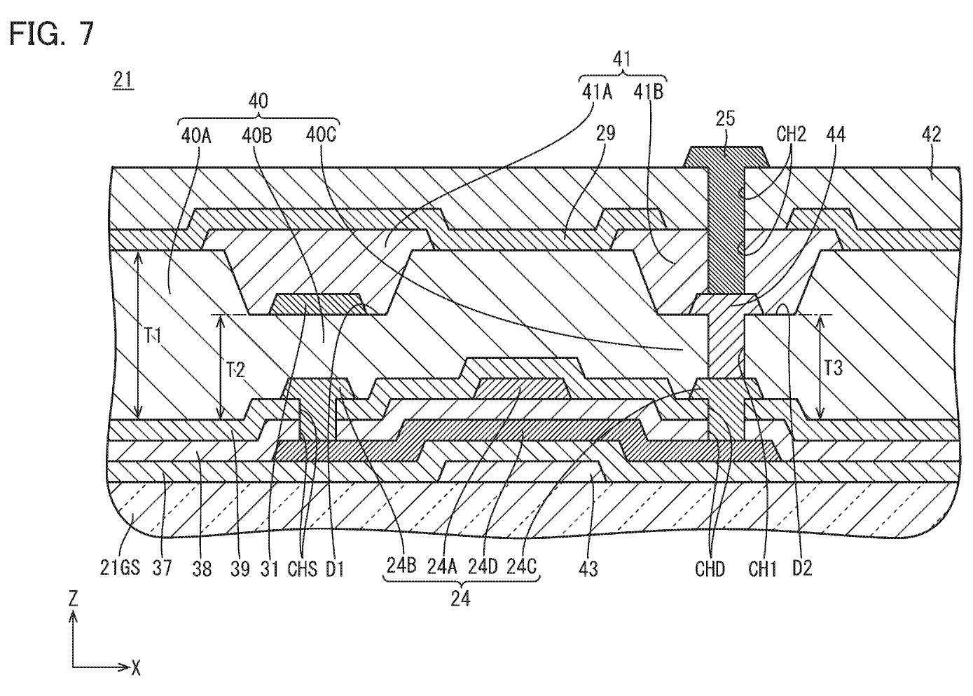

Various types of film stacked at the side of the inner surface of the array substrate 21 are described here with reference to FIGS. 5 to 7. FIG. 5 shows a cross-sectional configuration of a pixel electrode 25 or other components of the array substrate 21 as taken along an X-axis direction. FIGS. 6 and 7 show a cross-sectional configuration of a TFT 24 of the array substrate 21 and an area therearound. On the glass substrate (substrate) 21GS of the array substrate 21, as shown in FIGS. 5 to 7, at least a first metal film, a basecoat film 37, a semiconductor film, a gate insulating film 38, a second metal film, a first interlayer insulating film 39, a third metal film (second conducting film), a first planarizing film (first insulating film) 40, a fourth metal film (first conducting film), a second planarizing film (second insulating film) 41, a first transparent electrode film, a third planarizing film (third insulating film) 42, a second transparent electrode film, and an alignment film (not illustrated) are stacked in this order from a lower layer side (glass substrate 21GS side).

The first metal film, the second metal film, the third metal film, and the fourth metal film each have electric conductivity by being a single-layer film composed of one type of metal material or a laminated film or alloy composed of different types of metal material. The first metal film constitutes the after-mentioned light shield 43 or other components. The second metal film constitutes the gate wire 26, the gate electrode 24A of the TFT 24, or other components. The third metal film constitutes the source wire 27, the source electrode 24B and drain electrode 24C of the TFT 24, or other components. The fourth metal film constitutes the after-mentioned intermediate electrode (third electrode) 44 or other components in addition to the touch wires 30 and the heater wires 31. The semiconductor film is made of a polysilicon semiconductor material (semiconductor material) having a crystalline substance prepared by a publicly-known method such as laser crystallization. The polysilicon semiconductor material of the semiconductor film is high in electron mobility than an amorphous silicon semiconductor material and an oxide semiconductor material. The semiconductor film constitutes the semiconductor component 24D of the TFT 24 or other components. The first transparent electrode film and the second transparent electrode film are made of a transparent electrode material (e.g. ITO (indium tin oxide) or IZO (indium zinc oxide)). The first transparent electrode film constitutes the touch electrodes 29 or other components. The second transparent electrode film constitutes the pixel electrode 25 or other components.

The basecoat film 37, the gate insulating film 38, and the first interlayer insulating film 39 are each composed of SiO₂ (oxide silicon, Si oxide), SiNₓ (silicon nitride), or other inorganic materials (inorganic resin material). The first planarizing film 40, the second planarizing film 41, and the third planarizing film 42 are made of an organic material such as PMMA (acrylic resin). The film thicknesses of the first planarizing film 40, the second planarizing film 41, and the third planarizing film 42 are usually greater than the film thicknesses of the basecoat film 37, the gate insulating film 38, and the first interlayer insulating film 39. Specifically, while the film thicknesses of the basecoat film 37, the gate insulating film 38, and the first interlayer insulating film 39, which are made of an inorganic material, are, for example, approximately several tens of nanometers to several hundreds of nanometers, the film thicknesses of the first planarizing film 40, the second planarizing film 41, and the third planarizing film 42, which are made of an organic material, are, for example, approximately 1 μm to 3 μm. An inner surface of the array substrate 21 (that faces the liquid crystal layer 22) is planarized by the first planarizing film 40, the second planarizing film 41, and the third planarizing film 42. The basecoat layer 37 is sandwiched between the first metal film and the semiconductor film. The gate insulating film 38 is sandwiched between the semiconductor film and the second metal film. The first interlayer insulating film 39 is sandwiched between the second metal film and the third metal film. The first planarizing film 40 is sandwiched between the third metal film and the fourth metal film. The second planarizing film 41 is sandwiched between the fourth metal film and the first transparent electrode film. The third planarizing film 42 is sandwiched between the first transparent electrode film and the second transparent electrode film.

Cross-sectional configurations of the touch wires 30 and the heater wires 31 are described. As shown in FIG. 5, each of the touch wires 30 is placed in such a manner as to, when seen in a plan view, overlap a particular source wire 27 included in the plurality of source wires 27 placed at spacings in the X-axis direction in the display area AA. The sandwiching of the first planarizing film 40 between the touch wire 30, which is composed of part of the fourth metal film, and the source wire 27, which is composed of the third metal film, inhibits the wires 27 and 30 from becoming short-circuited with each other. The touch wire 30 extends substantially along the Y-axis direction in the same manner as the source wire 27 that the touch wire 30 overlaps. An end portion of the touch wire 30 leading to the first end portion 21A of the array substrate 21 in the non-display area NAA (i.e. an end portion that faces the flexible substrate 14) is connected to a lead wire (not illustrated). This lead wire, which is connected to the flexible substrate 14, is composed, for example, of part of the third metal film and may be connected to the touch wire 30 through a contact hole provided in the first planarizing film 40.

As shown in FIG. 5, each of the heater wires 31 is placed in such a manner as to, when seen in a plan view, overlap a source wire 27, included in the source wires 27 placed at spacings in the X-axis direction in the display area AA, that is different from the source wire 27 that overlaps the touch wire 30. The sandwiching of the first planarizing film 40 between the heater wire 31, which is composed of part of the fourth metal film, and the source wire 27, which is composed of the third metal film, inhibits the wires 27 and 31 from becoming short-circuited with each other. The heater wire 31 extends substantially along the Y-axis direction in the same manner as the source wire 27 that the heater wire 31 overlaps. Both end portions of the heater wire 31 located in the non-display area NAA are connected to the aforementioned trunk wires 32 and 33 (see FIG. 4). Thus, in the present embodiment, the touch wire 30 and the heater wire 31 are constituted by parts of the fourth metal film. This makes it possible to make the number of metal films smaller than in a case where the touch wire 30 and the heater wire 31 are constituted by different metal films. This reduces the number of steps for manufacturing the array substrate 21.

A cross-sectional configuration of the TFT 24 is described. As shown in FIGS. 6 and 7, the TFT 24 according to the present embodiment is of a so-called top-gate type in which the gate electrode 24A, which is composed of part of the second metal film, is disposed at a higher layer than the semiconductor component 24D, which is composed of part of the semiconductor film, to overlap the semiconductor component 24D via the gate insulating film 38. While both end portions of the semiconductor component 24D that do not overlap the gate electrode 24A are resistance-decreased regions made low in resistance, a central portion of the semiconductor component 24D that overlaps the gate electrode 24A is a non-resistance-decreased region that is not made low in resistance. The resistance-decreased regions of the semiconductor component 24D are formed by performing a resistance-decreasing process with the gate electrode 24A as a mask, for example, in the process of manufacturing the array substrate 21. The array substrate 21 is provided with a light shield 43 that overlaps at least the non-resistance-decreased region of the semiconductor component 24D. The light shield 43 is composed of part of the first metal film. The light shield 43, which is placed at a lower layer than the non-resistance-decreased region of the semiconductor component 24D, can block light that is shone on the non-resistance-decreased region of the semiconductor component 24D from the backlight device. This makes it possible to reduce fluctuations in the characteristics of the TFT 24 that can occur in a case where the non-resistance-decreased region of the semiconductor component 24D is irradiated with light.

As shown in FIGS. 6 and 7, the source electrode 24B of the TFT 24 is composed of part of the third metal film, and is disposed to overlap one resistance-decreased region (one end portion) of the semiconductor component 24D via the gate insulating film 38 and the first interlayer insulating film 39. The gate insulating film 38 and the first interlayer insulating film 39 have a source contact hole CHS bored through portions of the gate insulating film 38 and the first interlayer insulating film 39 that overlap both the source electrode 24B and the semiconductor component 24D. The source electrode 24B and the semiconductor component 24D are connected to each other through the source contact hole CHS. The drain electrode 24C of the TFT 24 is composed of part of the third metal film, and is disposed to overlap the other resistance-decreased region (other end portion) of the semiconductor component 24D via the gate insulating film 38 and the first interlayer insulating film 39. The gate insulating film 38 and the first interlayer insulating film 39 have a drain contact hole CHD bored through portions of the gate insulating film 38 and the first interlayer insulating film 39 that overlap both the drain electrode 24C and the semiconductor component 24D. The drain electrode 24C and the semiconductor component 24D are connected to each other through the drain contact hole CHD.

As shown in FIGS. 6 and 7, the TFT 24 includes an intermediate electrode 44 located in between the drain electrode 24C, which is composed of part of the third metal film, and the pixel electrode 25, which is composed of part of the second transparent electrode film. The intermediate electrode 44 is composed of part of the fourth metal film (i.e. a portion of the fourth metal film that is different from the touch wires 30 and the heater wires 31). The intermediate electrode 44 is disposed at a higher layer than the drain electrode 24C to overlap the drain electrode 24C via the first planarizing film 40. The intermediate electrode 44 is disposed at a lower layer than part of the pixel electrode 25 (i.e. a portion of the pixel electrode 25 that overlaps the drain electrode 24C of the TFT 24) to overlap the part of the pixel electrode 25 via the second planarizing film 41 and the third planarizing film 42. The first planarizing film 40, which is sandwiched between the drain electrode 24C and the intermediate electrode 44, has a first contact hole CH1 provided in a portion of the first planarizing film 40 that overlaps both the drain electrode 24C and the intermediate electrode 44. The drain electrode 24C and the intermediate electrode 44 are connected to each other through the first contact hole CH1 of the first planarizing film 40. The second planarizing film 41 and the third planarizing film 42, which are sandwiched between the intermediate electrode 44 and the pixel electrode 25, have a second contact hole CH2 bored through portions of second planarizing film 41 and the third planarizing film 42 that overlap both the intermediate electrode 44 and the pixel electrode 25. The intermediate electrode 44 and the pixel electrode 25 are connected to each other through the second contact hole CH2 of the second planarizing film 41 and the third planarizing film 42. Thus, the drain electrode 24C is relay-connected to the pixel electrode 25 via the intermediate electrode 44.

As shown in FIGS. 5 to 7, the first planarizing film 40 of the array substrate 21 according to the present embodiment has a first insulating portion 40A and a second insulating portion 40B that is smaller (thinner) in film thickness than is the first insulating portion 40A. Whereas first insulating portion 40A has a thickness T1, the second insulating portion 40B has a thickness T2, and a relationship "T1 > T2" holds. The first insulating portion 40A is located under the touch wire 30, which is composed part of at least the fourth metal film. In addition, the first insulating portion 40A is also present, for example, in an area that overlaps a large portion of the pixel electrode 25. That is, the first insulating portion 40A constitutes a large portion of the first planarizing film 40 excluding the second insulating portion 40B and the after-mentioned fourth insulating portion 40C.

As shown in FIGS. 5 to 7, the second insulating portion 40B is located under the heater wire 31, which is composed part of at least the fourth metal film. Specifically, the second insulating portion 40B extends along the Y-axis direction in such a manner as to run parallel to the heater wire 31 and is present in a band (linear) area that is wider in width than is the heater wire 31. A surface of the first planarizing film 40 has a first depression D1 formed in a range of formation of the second insulating portion 40B. The height of the first depression D1 assumes a value ("T1 - T2") obtained by subtracting the thickness T2 of the second insulating portion 40B from the thickness T1 of the first insulating portion 40A. Further, the width of the first depression D1 is equal to the width of the second insulating portion 40B. Thus, the first planarizing film 40, which includes the first insulating portion 40A and the second insulating portion 40B, which are different in film thickness, is patterned by being exposed and developed with a half-tone mask or a gray-tone mask in the process of manufacturing the array substrate 21.

On the other hand, as shown in FIGS. 5 to 7, the second planarizing film 41 has a third insulating portion 41A disposed not to overlap the touch wire 30 and to overlap the heater wire 31. According to such a configuration, the heater wire 31 is kept insulated by the third insulating portion 41A from another electrode (e.g. the touch electrode 29) or other wires placed at a higher layer than the second planarizing film 41 and therefore can avoid becoming short-circuited. Of the first planarizing film 40, the second insulating portion 40B, which is placed under the heater wire 31, is smaller in film thickness than is the first insulating portion 40A, which is placed under the touch wire 30. On the other hand, the third insulating portion 41A is disposed not to overlap the touch wire 30 and to overlap the heater wire 31. Accordingly, the difference between the sum of the film thicknesses of the second insulating portion 40B and the third insulating portion 41A over the heater wire 31 and the film thickness of the first insulating portion 40A becomes smaller by the difference between the film thicknesses of the first insulating portion 40A and the second insulating portion 40B. This relaxes film stress on the array substrate 21, thus making the array substrate 21 less prone to warpage.

Specifically, as shown in FIGS. 5 and 7, as with the second insulating portion 40B, the third insulating portion 41A extends along the Y-axis direction in such a manner as to run parallel to the heater wire 31 and is present in a band (linear) area that is wider in width than is the heater wire 31. More specifically, the third insulating portion 41A is placed in such an area as to overlap the whole area of the second insulating portion 40B and to run on an edge of the first insulating portion 40A that is adjacent to the second insulating portion 40B (i.e. an area larger than the first depression D1). That is, the third insulating portion 41A is selectively provided in such a manner as to fill the first depression D1 formed by the second insulating portion 40B in the first planarizing film 40. Thus, unlike the first planarizing film 40 and the third planarizing film 42, which are solidly present substantially all over the display area AA, the second planarizing film 41 is patterned to be present locally in the display area AA. The third insulating portion 41A has a thickness that is about equal to or larger than the height of the first depression D1. Such a configuration allows the touch electrode 29, which is placed over the third insulating portion 41A, to be satisfactorily planarized, thus making the touch electrode 29 less prone to breakage and attaining satisfactory position detection sensitivity (touch sensitivity).

As noted above, as shown in FIGS. 5 to 7, the second planarizing film 41 is selectively placed so that the third insulating portion 41A overlaps the heater wire 31 in the display area AA, and is not formed in an area overlapping the touch wire 30. Accordingly, the touch wire 30, which is placed over the first insulating portion 40A of the first planarizing film 40 and composed of part of the fourth metal film, and the touch electrode 29, which is composed of part of the first transparent electrode, make direct contact with each other without the second planarizing film 41 sandwiched therebetween, thereby making an electrical connection. On the other hand, the touch electrode 29 is disposed to overlap the heater wire 31 via the third insulating portion 41A. Although the heater wire 31 overlaps the touch electrode 29, the heater wire 31 is kept insulated from the touch electrode 29 by the third insulating portion 41A sandwiched therebetween.

Furthermore, as shown in FIGS. 6 and 7, the first planarizing film 40 has a fourth insulating portion 40C that is smaller in film thickness than is the first insulating portion 40A. The fourth insulating portion 40C is disposed to overlap the drain electrode 24C, which constitutes the TFT 24. Specifically, the fourth insulating portion 40C is present in an island-shaped area that, when seen in a plan view, is a size larger than is the drain electrode 24C. A surface of the first planarizing film 40 has a second depression D2 formed in a range of formation of the fourth insulating portion 40C. The height of the second depression D2 assumes a value ("T1 - T3") obtained by subtracting the thickness T3 of the fourth insulating portion 40C from the thickness T1 of the first insulating portion 40A. In the present embodiment, the thickness T3 of the fourth insulating portion 40C is equal to the thickness T2 of the second insulating portion 40B. Accordingly, it can be said that the first planarizing film 40 is configured so that a relationship "T1 > T3 = T2" holds. This makes it possible to, in manufacturing the array substrate 21, form together the second insulating portion 40B and the fourth insulating portion 40C, which are smaller in film thickness than is the first insulating portion 40A, by patterning the first planarizing film 40. This makes it possible to shorten the tact time to pattern the first planarizing film 40. Further, the first contact hole CH1 is provided in the fourth insulating portion 40C of the first planarizing film 40 that overlaps both the drain electrode 24C and the intermediate electrode 44.

On the other hand, as shown in FIGS. 6 and 7, the second planarizing film 41 has a fifth insulating portion 41B disposed not to overlap the touch wire 30 and the heater wire 31 and to overlap the intermediate electrode 44. According to such a configuration, the intermediate electrode 44 is kept insulated by the fifth insulating portion 41B from another electrode (e.g. the touch electrode 29) or other wires placed at a higher layer than the second planarizing film 41 and therefore can avoid becoming short-circuited. Of the first planarizing film 40, the fourth insulating portion 40C, which is placed under the intermediate electrode 44, is smaller in film thickness than is the first insulating portion 40A, which is placed under the touch wire 30. On the other hand, the fifth insulating portion 41B is disposed not to overlap the touch wire 30 and the heater wire 31 and to overlap the intermediate electrode 44. Accordingly, the difference between the sum of the film thicknesses of the fourth insulating portion 40C and the fifth insulating portion 41B over the intermediate electrode 44 and the film thickness of the first insulating portion 40A becomes smaller by the difference between the film thicknesses of the first insulating portion 40A and the fourth insulating portion 40C. This relaxes film stress on the array substrate 21, thus making the array substrate 21 less prone to warpage.

Specifically, as shown in FIGS. 6 and 7, the fifth insulating portion 41B is present in an island-shaped area that, when seen in a plan view, is a size larger than is the intermediate electrode 44. More specifically, the fifth insulating portion 41B is placed in such an area as to overlap the whole area of the fourth insulating portion 40C and to run on an edge of the first insulating portion 40A that is adjacent to the fourth insulating portion 40C (i.e. an area larger than the second depression D2). That is, the fifth insulating portion 41B is selectively provided in such a manner as to fill the second depression D2 formed by the fourth insulating portion 40C in the first planarizing film 40. The fifth insulating portion 41B has a thickness that is about equal to or larger than the height of the second depression D2. Such a configuration allows the touch electrode 29, which is placed over the fifth insulating portion 41B, to be satisfactorily planarized, thus making the touch electrode 29 less prone to breakage and attaining satisfactory position detection sensitivity. Further, the second contact hole CH2 is provided in the fifth insulating portion 41B of the second planarizing film 41 that overlaps both the intermediate electrode 44 and the pixel electrode 25.

As described above, an array substrate (wiring substrate) 21 of the present embodiment includes a first planarizing film (first insulating film) 40 having a first insulating portion 40A and a second insulating portion 40B that is smaller in film thickness than is the first insulating portion 40A, a touch wire (first wire) 30 placed over the first insulating portion 40A and composed of part of a fourth metal film (first conducting film) placed at a higher layer than the first planarizing film 40, a heater wire (second wire) 31 placed over the second insulating portion 40B and composed of part of the fourth metal film, and a second planarizing film (second insulating film) 41, placed at a high layer than the fourth metal film, that has a third insulating portion 41A disposed not to overlap the touch wire 30 and to overlap the heater wire 31.

The touch wire 30 and the heater wire 31 are constituted by parts of the fourth metal film. This makes it possible to make the number of metal films smaller than in a case where the touch wire 30 and the heater wire 31 are constituted by different metal films (conducting films). This reduces the number of steps for manufacturing the array substrate 21. The second planarizing film 41 has the third insulating portion 41A, which is disposed to overlap the heater wire 31, so that the heater wire 31 and another electrode or other wires placed at a higher layer than the second planarizing film 41 are inhibited from becoming short-circuited with each other. Of the first planarizing film 40, the second insulating portion 40B, which is placed under the heater wire 31, is smaller in film thickness than is the first insulating portion 40A, which is placed under the touch wire 30. On the other hand, the third insulating portion 41A is disposed not to overlap the touch wire 30 and to overlap the heater wire 31. Accordingly, the difference between the sum of the film thicknesses of the second insulating portion 40B and the third insulating portion 41A over the heater wire 31 and the film thickness of the first insulating portion 40A becomes smaller by the difference between the film thicknesses of the first insulating portion 40A and the second insulating portion 40B. This relaxes film stress on the array substrate 21, thus making the array substrate 21 less prone to warpage.

Further, the array substrate 21 may further include a touch electrode (first electrode) 29 composed of part of a first transparent electrode film placed at a higher layer than the second planarizing film 41. The touch electrode 29 may be disposed to be in contact with the touch wire 30 and to overlap the heater wire 31 via the third insulating portion 41A. The touch wire 30 is connected by making direct contact with the touch electrode 29, which is composed of part of the first transparent electrode film. Although the heater wire 31 overlaps the touch electrode 29, the heater wire 31 is kept insulated from the touch electrode 29 by the third insulating portion 41A sandwiched therebetween.

Further, the first wire may serve as a touch wire (position detecting wire) 30 that transmits a position detection signal, and the first electrode may serve as a touch electrode (position detecting electrode) 29 that forms a capacitance with a position input body that performs position input. The first electrode, which is the touch electrode 29, can form a capacitance with a position input body that performs position input and detect an input position with the position input body by utilizing a position detection signal that is supplied by the first wire, which is the touch wire 30.

Further, the second planarizing film 41 may be made of an organic material. The third insulating portion 41A of the second planarizing film 41, which is made of an organic material, causes the touch electrode 29 to be planarized. This makes the touch electrode 29 less prone to breakage. Further, in a case where the touch electrode 29 serves as a position detection electrode, satisfactory position detection sensitivity is attained by the position detecting electrode being planarized.

Further, the third insulating portion 41A may be placed in such an area as to overlap the second insulating portion 40B and to run on an edge of the first insulating portion 40A that is adjacent to the second insulating portion 40B. The third insulating portion 41A is placed in such a manner as to fill a first depression (depression) D1 formed by the first planarizing film 40 having the second insulating portion 40B. This allows the touch electrode 29 to be satisfactorily planarized, thus making the touch electrode 29 less prone to breakage.

The array substrate 21 may further include a drain electrode (second electrode) 24C composed of part of a third metal film (second conducting film) placed at a lower layer than the first planarizing film 40, an intermediate electrode (third electrode) 44 composed of part of the four metal film and disposed to overlap the drain electrode 24C, a third planarizing film (third insulating film) 42 placed at a higher layer than the second planarizing film 41, and a pixel electrode (fourth electrode) 25 and disposed to at least partially overlap the intermediate electrode 44 and composed of part of a second transparent electrode film placed at a higher layer than the third planarizing film 42. The first planarizing film 40 may have a fourth insulating portion 40C that is smaller in film thickness than is the first insulating portion 40A and that is disposed to overlap the drain electrode 24C. The second planarizing film 41 may have a fifth insulating portion 41B disposed not to overlap the touch wire 30 and the heater wire 31 and to overlap the intermediate electrode 44. The fourth insulating portion 40C may have a first contact hole CH1, provided in a portion of the fourth insulating portion 40C that overlaps both the drain electrode 24C and the intermediate electrode 44, through which the drain electrode 24C and the intermediate electrode 44 are connected to each other. The fifth insulating portion 41B and the third planarizing film 42 may have a second contact hole CH2, bored through portions of the fifth insulating portion 41B and the third planarizing film 42 that overlap both the third electrode and the fourth electrode, through which the intermediate electrode 44 and the pixel electrode 25 are connected to each other. The drain electrode 24C, which is composed of part of the third metal film, and the intermediate electrode 44, which is composed of part of the fourth metal film, are connected to each other through the first contact hole CH1, which is provided in the fourth insulating portion 40C of the first planarizing film 40 sandwiched therebetween. The intermediate electrode 44, which is composed of part of the fourth metal film, and the pixel electrode 25, which is composed of part of the second transparent electrode film, are connected to each other through the second contact hole CH2 bored through the fifth insulating portion 41B and the third planarizing film 42 sandwiched therebetween. Thus, the pixel electrode 25 is connected to the drain electrode 24C via the intermediate electrode 44. Moreover, of the first planarizing film 40, the fourth insulating portion 40C, which overlaps the drain electrode 24C, is smaller in film thickness than is the first insulating portion 40A. On the other hand, the fifth insulating portion 41B is disposed not to overlap the touch wire 30 and the heater wire 31 and to overlap the drain electrode 24C. Accordingly, the difference between the sum of the film thicknesses of the fourth insulating portion 40C and the fifth insulating portion 41B over the drain electrode 24C and the film thickness of the first insulating portion 40A becomes smaller by the difference between the film thicknesses of the first insulating portion 40A and the second insulating portion 40B. This relaxes film stress on the array substrate 21, thus making the array substrate 21 less prone to warpage.

Further, the fourth insulating portion 40C may be equal in film thickness to the second insulating portion 40B. The second insulating portion 40B and the fourth insulating portion 40C, which are smaller in film thickness than is the first insulating portion 40A, can be formed together by patterning the first planarizing film 40. This makes it possible to shorten the tact time to pattern the first planarizing film 40.

Further, the second wire may serve as a heater wire 31 that generates heat when energized. The heater wire 31, which generates heat when energized, can suppress a drop in temperature of the array substrate 21, for example, even in a cold environment.

Further, a liquid crystal panel (display device) 11 of the present embodiment includes the array substrate 21 and a counter substrate 20 facing the array substrate 21. Such a liquid crystal panel 11 makes it possible to reduce the number of steps for manufacturing the array substrate 21 and reduce warpage of the array substrate 21, thus bringing about improvement in producibility of the liquid crystal panel 11.

Further, the liquid crystal panel 11 may further include a liquid crystal layer 22 sandwiched between the array substrate 21 and the counter substrate 20. The first wire may serve as a heater wire 31 that generates heat when energized. The liquid crystal layer 22, which is sandwiched between the array substrate 21 and the counter substrate 20, improves in response speed by being heated by the heater wire 31. Improvement in response speed of the liquid crystal layer 22 can lead to improvement in display quality.

### Other Embodiments

The present disclosure is not limited to the embodiments described with reference to the foregoing description and drawings. For example, embodiments such as those listed below are encompassed in the technical scope.

(1) The specific ranges of formation of the second insulating portion 40B and the third insulating portion 41A in a plan view are subject to appropriate change other than those illustrated. For example, the third insulating portion 41A may be placed in such an area as not to run on an edge of the first insulating portion 40A that is adjacent to the second insulating portion 40B (i.e. in the same area as the first depression D1).

(2) The thickness of the third insulating portion 41A may assume a value that is less than the height of the first depression D1.

(3) The specific ranges of formation of the fourth insulating portion 40C and the fifth insulating portion 41B in a plan view are subject to appropriate change other than those illustrated. For example, the fifth insulating portion 41B may be placed in such an area as not to run on an edge of the first insulating portion 40A that is adjacent to the fourth insulating portion 40C (i.e. in the same area as the second depression D2).

(4) The thickness of the fifth insulating portion 41B may assume a value that is less than the height of the second depression D2.

(5) The placement and planar shapes of the touch electrodes 29 and the touch wires 30 in a plan view are subject to appropriate change other than those illustrated.

(6) An insulating film made of an inorganic material may be added between the touch wires 30 and the touch electrodes 29. In that case, even if a touch electrode 29 and a touch wire 30 that is not to be connected to the touch electrode 29 overlap each other, the insulating film sandwiched between the touch electrode 29 and the touch wire 30 can keep the touch electrode 29 and the touch wire 30 insulated from each other.

(7) The array substrate 21 may have a second interlayer insulating film placed at a higher layer than the second transparent electrode film and made of an inorganic material and a second transparent electrode film placed at a higher layer than the second interlayer insulating film. In this case, a "common electrode" can be provided by the second transparent electrode film. The common electrode overlaps all pixel electrodes 25 placed in the display area AA and serves to generate electric fields with the pixel electrodes 25. Providing slits in portions of the common electrode that overlap the pixel electrodes 25 allows the liquid crystal panel 11 to operate in an FFS (fringe field switching) mode or other modes.

(8) The counter substrate 20 may have a counter electrode that faces each pixel electrode 25 across the liquid crystal layer 22. This allows the liquid crystal panel 11 to operate in a VA (vertical alignment) mode or other modes.

(9) An insulating film made of an inorganic material can be provided in place of the third planarizing film 42. In that case, the spacings between the touch electrodes 29 and the pixel electrodes 25 are sufficiently small, so that the touch electrodes 29 are allowed to function as a "common electrode". The common electrode overlaps all pixel electrodes 25 placed in the display area AA and serves to generate electric fields with the pixel electrodes 25. Providing slits in portions of the common electrode that overlap the pixel electrodes 25 allows the liquid crystal panel 11 to operate in the FFS mode or other modes. In such a configuration, touch signals pertaining to the touch panel function and common potential signals (reference potential signals) pertaining to the display function are supplied from the touch panel controller 16C to the touch wires 30 at different timings (i.e. in a time-division manner).

(10) In (9) above, it is also possible to omit the touch panel function, use the touch wires 30 as "common wires", and use the touch electrodes 29 as a "common electrode". The common wires serve to transmit only the common potential signals pertaining to the display function. Th common electrode is an undivided structure and is disposed to extend all over the display area AA.

(11) The "second wire" may be a wire other than the heater wire 31, i.e. a wire that does not principally involve the heater function.

(12) The TFT 24 may have a bottom-gate structure, i.e. a structure in which the gate electrode 24A is disposed at a lower layer than the semiconductor component to overlap the semiconductor component.

(13) It is also possible to omit the light shield 43. In that case, the first metal film may be removed, which gives three metal films.

(14) The driver 15 may be mounted on the first end portion 21A of the array substrate 21 by COG (Chip on Glass). In that case, the display terminal areas connected to the flexible substrate 14 are connected to the source wires 27 or other wires via the driver 15.

(15) The touch panel controller 16C may be provided on the flexible substrate 14 or other substrates.

(16) It is also possible to omit the circuit unit 12. In that case, gate drivers having functions similar to those of the circuit unit 12 may be attached to the array substrate 21. Further, it is also possible to provide the circuit unit 12 on only one side of each of the array substrate 21.

(17) The semiconductor component 24D may be constituted by semiconductor films made of a material such as amorphous silicon or an oxide semiconductor material.

(18) The planar shape of the liquid crystal panel 11 may be a vertically long rectangle, a regular square, a circle, a semicircle, an oval, an ellipse, a trapezoid, or other shapes.

(19) The liquid crystal panel 11 may be of a reflective type or a semi-transmissive type instead of being of a transmissive type. In a case where the liquid crystal panel 11 is of a reflective type, the backlight device can be omitted.

(20) The liquid crystal panel 11 may be replaced by another display panel (such as an organic EL display panel).

The present disclosure contains subject matter related to that disclosed in Japanese Priority Patent Application JP 2025-020078 filed in the Japan Patent Office on February 10, 2025, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A wiring substrate comprising:
a first insulating film having a first insulating portion and a second insulating portion that is smaller in film thickness than is the first insulating portion;
a first wire placed over the first insulating portion and composed of part of a first conducting film placed at a higher layer than the first insulating film;
a second wire placed over the second insulating portion and composed of part of the first conducting film; and
a second insulating film, placed at a high layer than the first conducting film, that has a third insulating portion disposed not to overlap the first wire and to overlap the second wire.

2. The wiring substrate according to claim 1, further comprising a first electrode composed of part of a first transparent electrode film placed at a higher layer than the second insulating film,
wherein the first electrode is disposed to be in contact with the first wire and to overlap the second wire via the third insulating portion.

3. The wiring substrate according to claim 2, wherein
the first wire serves as a position detecting wire that transmits a position detection signal, and
the first electrode serves as a position detecting electrode that forms a capacitance with a position input body that performs position input.

4. The wiring substrate according to claim 2, wherein the second insulating film is made of an organic material.

5. The wiring substrate according to claim 4, wherein the third insulating portion is placed in such an area as to overlap the second insulating portion and to run on an edge of the first insulating portion that is adjacent to the second insulating portion.

6. The wiring substrate according to claim 1, further comprising:
a second electrode composed of part of a second conducting film placed at a lower layer than the first insulating film;
a third electrode composed of part of the first conducting film and disposed to overlap the second electrode;
a third insulating film placed at a higher layer than the second insulating film; and
a fourth electrode disposed to at least partially overlap the third electrode and composed of part of a second transparent conductive film placed at a higher layer than the third insulating film,
wherein
the first insulating film has a fourth insulating portion that is smaller in film thickness than is the first insulating portion and that is disposed to overlap the second electrode,
the second insulating film has a fifth insulating portion disposed not to overlap the first wire and the second wire and to overlap the third electrode,
the fourth insulating portion has a first contact hole, provided in a portion of the fourth insulating portion that overlaps both the second electrode and the third electrode, through which the second electrode and the third electrode are connected to each other, and
the fifth insulating portion and the third insulating film have a second contact hole, bored through portions of the fifth insulating portion and the third insulating film that overlap both the third electrode and the fourth electrode, through which the third electrode and the fourth electrode are connected to each other.

7. The wiring substrate according to claim 6, wherein the fourth insulating portion is equal in film thickness to the second insulating portion.

8. The wiring substrate according to claim 1, wherein the second wire serves as a heater wire that generates heat when energized.

9. A display device comprising:
the wiring substrate according to claim 1; and
a counter substrate facing the wiring substrate.

10. The display device according to claim 9, further comprising a liquid crystal layer sandwiched between the wiring substrate and the counter substrate,
wherein the second wire serves as a heater wire that generates heat when energized.
